(19) United States
(12) Patent Application Publication
(10) Pub. No.: US 2025/0189666 A1
(43) Pub. Date: Jun. 12, 2025

(54) DYNAMIC SAMPLING RATE

(71) Applicant: Elliptic Laboratories ASA, Oslo (NO)

(72) Inventor: Espen KLOVNING, Strømmen (NO)

(73) Assignee: Elliptic Laboratories ASA, Oslo (NO)

(21) Appl. No.: 18/845,760

(22) PCT Filed: Dec. 21, 2022
(86) PCT No.: PCT/EP2022/087274

§ 371 Date: Sep. 10, 2024

(30) Foreign Application Priority Data
Mar. 31, 2022 (NO) 20220394

(51) Int. Cl. G01S 15/04; H04R 3/04

(52) U.S. Cl. CPC G01S 15/04; H04R 3/04

(57) ABSTRACT

A method and device for assuring at least a signal is received undistorted, wherein the method and device including at least one first transducer for receiving acoustic signals in a predetermined frequency band and digitizing said acoustic signals at a predetermined sampling rate, at least one second transducer for transmitting acoustic signals in said predetermined frequency band corresponding to said predetermined sampling rate, an analyzing unit for comparing said transmitted acoustic signals with said received acoustic signals, wherein, the analyzing unit analyzes the quality of said received acoustic signals, detect at least one deviation between said transmitted acoustic signals and said received acoustic signals, and adjust said sampling rate and corresponding frequency band according to a set of predefined frequency bands and sampling rates.

### TECHNICAL FIELD

The present invention relates to a solution for reducing power consumption of an electronic device, specifically an electronic device using acoustic technology, more specifically electronic devices capable of transmitting and receiving ultrasound.

At present, some electronic devices, such as computers, cellphones and similar devices, have embedded activity detection (e.g. proximity, presence, gesture, etc) with the use of acoustic technology. In general, these electronic devices emit probe signals, such as a pulse shaped analog signal with a short and specified time duration from which the distance to an object of interest is determined by a time delay between a probe signal and its reflected signal from said object of interest. Another type of probe signal is a continuous signal, wherein doppler analysis is used to process the received echo to determine the detection of movement.

Said probe signals in electronic devices are generated by specifically a Digital to Analog Converter (DAC), or generally a codec with an embedded DAC, transforming encoded signals into analog signal. The probe signals are either narrowband signals, broadband signals or a combination thereof from one or more acoustic transmitters, e.g. from transducers such as computer speakers. The emitted signals are picked up by one or more acoustic receivers, e.g. other transducers such as microphones, wherein the received signals are further processed for encoding of the analog signal by an Analog to Digital Converter (ADC), or also a codec with an embedded ADC, wherein the ADC or codec is configured with the current sampling rate/frequency, Fs, which is the number of samples per second taken from a continuous analog signal in order to make a discrete or digital signal. In other words, the sampling rate, Fs, is the speed at which the ADC is sampling an analog input, or the sampling rate at which the DAC is sending out an analog output.

The sampling rate of the electronic devices receiving acoustic signals depend on the available sampling rate of the hardware platform. E.g. if the sampling rate is 48 KHz, the theoretical available ultrasound frequency range for transmitting devices will be below 24 KHz, wherein the sampling rate is defined by the Nyquist sampling theorem, wherein the sampling frequency, Fₛ, must be at least twice as high as the signal's highest frequency component, Fₛ≥2×Fₓ, in order to be perfectly reconstructed from its waveform samples. Since the ultrasound frequency band below 24 KHz is limited, the number of transmitting devices that can use the band simultaneously is also limited.

As a result of the limited bandwidth available, a technical issue that may occur in such systems is the detection of undesired interference in the frequency band used by the electronic device deriving either from one or more transmitting devices in the adjacent vicinity, or as noise from a third-party sound source, e.g. electric machine, rattling keychain, etc. Concerning activity detection, wherein an expected echo from the probe signal is instead replaced by uninterpretable noise as a result of the interference. Another undesired technical outcome is intermodulation distortion due to current acoustic signals, which may have a detrimental effect in analyzing received ultrasound signal.

One alternative scheme to avoid interference or intermodulation effects in order to properly sample transmitted signals is with the use of a known multiplexing scheme denoted Time Divisional Multiplexing (TDM), wherein each transmitting device can transmit their signal in allotted time slots. The TDM scheme is only viable if the output signal is non-continuous, wherein the signal is pulsed and can be transmitted within the allotted time slots. Some devices' signals may be allocated several consecutive time slots to match the duration of the pulsed signal or the duration may vary based on the length of the pulsed signal. Another viable scheme is Frequency Divisional Multiplexing (FDM), wherein the transmitting devices are allotted different, non-overlapping frequency bands to limit or prevent any kind of signal interference from other devices.

These schemes can also be combined, wherein the electronic device is using both schemes at the same time, e.g. wherein all the available frequency bands offer time slots to different transmitting devices.

In some use-cases, the detection is a sequential process. E.g. as in the case of presence detection, wherein during the initial sequence, the detection may be coarse. But once a detection is completed, the use-case may want to change detection scheme to do a more specific and accurate detection analysis given the current situation (e.g. improved resolution to do activity detection). In some cases, this will require a more wide-band signal which again may require the sampling rate of the acoustic system to be adapted to the current probe signal and increased when needed in order to sufficiently sample said signal perfectly as opposed to configuring the sampling rate to be viable for the highest possible frequency of the wide-band probe signal. At current, most platforms, i.e. most electronic devices, have arguably a standardized set, of available sampling rates, e.g. 16 KHz, 32 KHz, 48 KHz, 96 KHz, 192 KHz, etc.

But taking power usage in consideration, a higher sampling rate usually means increased power consumption due to an increase in memory usage, sampling frequencies and processing cycles. E.g. if a signal is transmitted at 26 KHz, a standardized sampling rate of 96 KHz, arguably a superfluous sampling rate for a 26 KHz signal resulting in excessive power consumption.

An alternative to limit the power consumption is to turn off input/output components and processing elements when the use-case processing is not needed. But when the use-case processing is enabled, a higher sampling rate may still be necessary due to the frequency of the probe signal, thus resulting in increased power consumption.

Certain use-cases require a continuous probe signal to ensure that the performance of the use-case is within the requirements. For such use-cases, TDM is not an option due to continuous signaling, therefore the only viable choice is to use FDM.

Given that there are available frequency bands, the use-case processing can change frequency band as it sees fit within the current sampling rate. In other cases, FDM is only an option if the device is both capable of increasing the sampling rate and the use-case processing can handle moving to another frequency band.

Even though all the electronic devices are of the same type or from the same vendor using similar output signal, pulse rate and/or interference handling schemes based on TDM or FDM or both, there is only a limited number of devices that can be supported within the same frequency band in the same limited space.

If the electronic devices are using more than one incompatible scheme to avoid interference, the number of current devices in the same limited space may be even lower.

### SUMMARY OF THE INVENTION

The object of the present invention is to monitor the ultrasound interference deriving from one or more transmitting devices which is received by an electronic device while limiting the power consumption of said electronic device by applying the lowest sampling rate possible to the probe signal output and input transducers and still reduce the effect of interference from other devices.

The sampling rate is controlled by the existing software or hardware modules generating the output signal and processing the input signal. If the receiving device does not know the frequency of the probe signal which in some cases may be transmitted by another module or another device in the same device, the receiving device may initially adjust to a predetermined high sampling rate that is sufficient to properly reconstruct the input signal from other devices or modules. Once the actual frequency range of the input signal is deduced by analyzing the received signal, the sampling rate is reduced to a predetermined and suitable sampling rate as described above to lower the power consumption of the input path and its processing.

It is also the object of the present invention to utilize the electronic device to dynamically increase or decrease the sampling rate of the input and output, if the frequency band of a probe signal is increased or decreased respectively in order to minimize the power consumption of the electronic device, regardless of the frequency of the current probe signal.

It is also the object of the present invention to utilize existing features in electronic devices, such as a computer, which may further include features such as transducers, e.g. speakers and microphones, are at least capable of operating in the audible range, 0 Hz-20 KHz, and ultrasound range, just outside the audible range, above 20 KHz. Thus, said electronic devices can function without any changes in hardware of an ordinary computer or similar electronic devices, although additional active or passive sensors may also be used.

The operation of said transducers require a certain power consumption and it is an additional object of the present invention to provide sufficient signal rate frequency bands in a dynamic manner without a significant increase in the power consumption of the device.

The present invention is aimed at solving the objects as stated above and this is achieved in the accompanying claims.

Certain features and functions of the present invention will be described with reference to the following figure(s) in which not every component may be labeled for the sake of clarity.

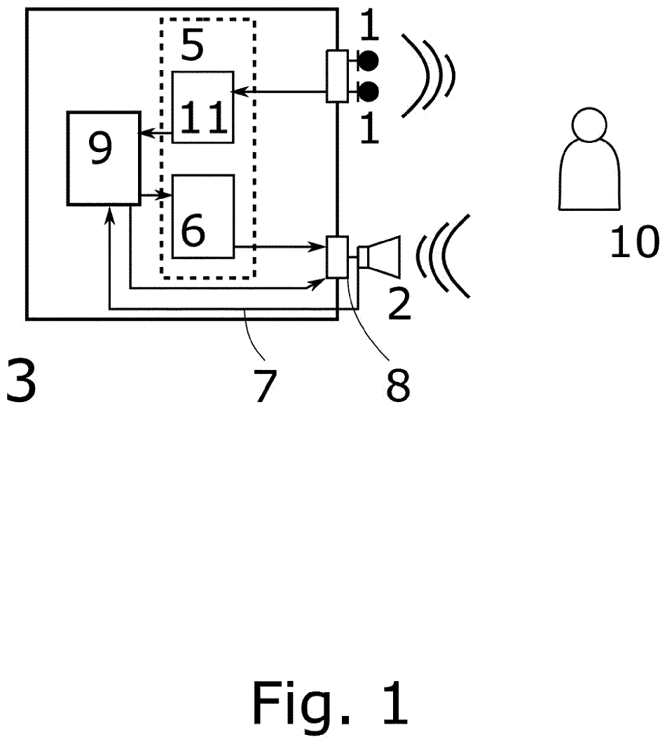

FIG. 1 illustrates an electronic device and external transmitters,

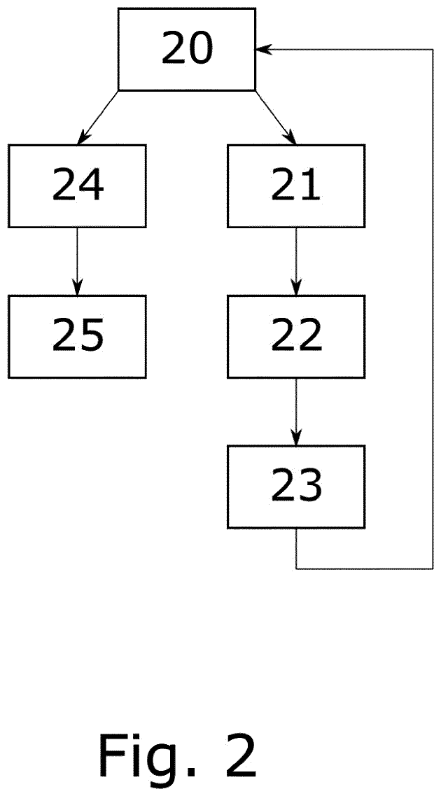

FIG. 2 illustrates a flow chart demonstrating how to change frequency band by increase the sampling rate when detecting interference,

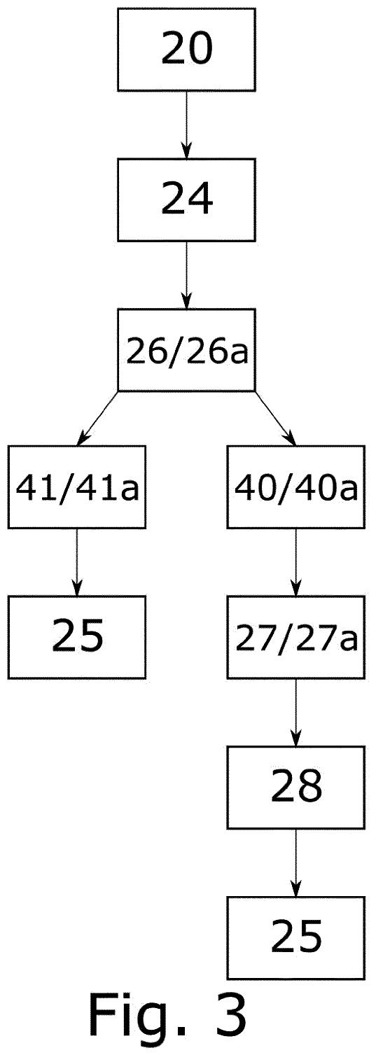

FIG. 3 illustrates a flow chart demonstrating how to decrease the sampling rate when not detecting interference,

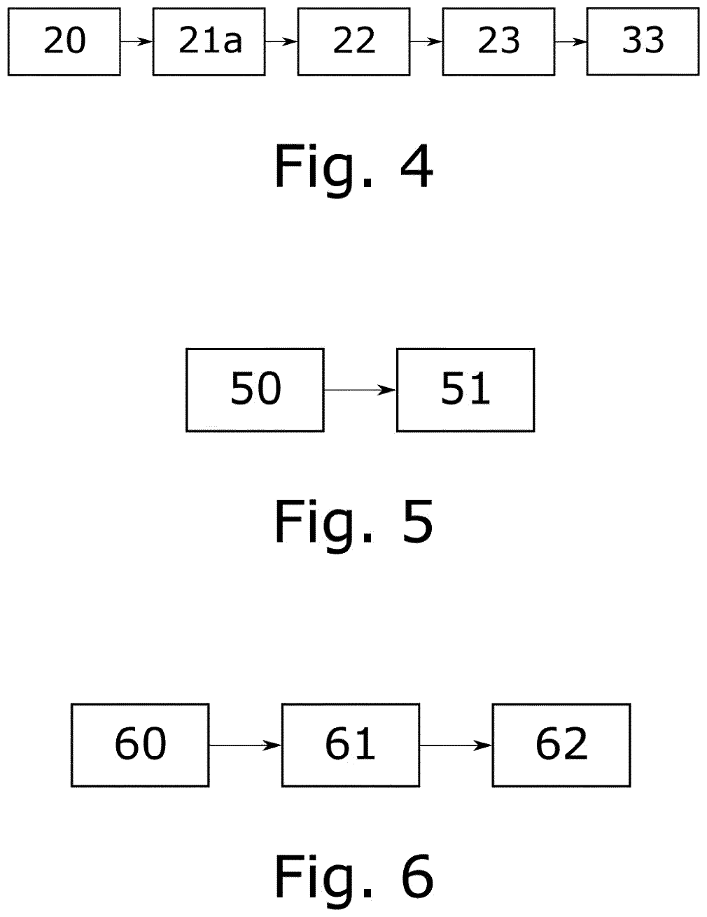

FIG. 4 illustrates a flow chart demonstrating how to increase the sampling rate to make available TDM time-slots,

FIG. 5 illustrates a flow chart demonstrating an embodiment where the probe signal is sampled at a lower sampling frequency,

FIG. 6 illustrates a flow chart demonstrating an embodiment where a filtering device is utilized to alter the probe signal's frequency band.

### DETAILED DESCRIPTION OF THE INVENTION

As illustrated in FIG. 1, the present invention relates to an electronic device 3 using at least one acoustic transducer 2, such as a speaker, transmitting acoustic signals, such as a probe signal, which is a transmitted acoustic signal at a predetermined frequency band, predetermined time duration, and preferably in the ultrasound range, e.g. for presence detection, and at least one microphone or transducer 1 continuously receiving analog signals reflected from an object, preferably a user 10 in the vicinity of the device.

The device 3 includes a processor 9 which receives and transmits data, such as encoded signals, and controls connected units 1, 2, 5, 6, 8, 11. The processor 9 controls first conversion unit or a DAC unit 6, which transforms encoded signals to generate acoustic signals through the acoustic transducer 2 with a predetermined sampling rate set by the processor 9. A filtering device 8 can also be connected in between the DAC unit 6 and acoustic transducer 2, as a means to alter the output acoustic signal as found necessary, controlled by the processor 9. While the acoustic signals or frequency bands are preferably in the near ultrasound range, e.g. 20 KHz-96 KHz, so as not to be noticeable adjacent user(s) 10, it may also be in the audible range 0 Hz-20 KHz, e.g. using specific frequencies in known acoustic signals such as music playback. The processor 9 also is also connected to and receives encoded analog signals from a second conversion unit or an ADC unit 11, wherein the analog signals were initially received by said at least one microphone or receiver 1. When the ADC unit 11 receives analog signals the processor 9 determines the sampling frequency/rate of the received analog signal and converts said analog signal to a digital signal, representing information in discrete values of analog bands.

Alternatively, in another embodiment a codec 5 can be included in the electronic device 3, having by itself the same overall functionality and connections as the first conversion unit, the DAC unit 6, and the second conversion unit, the ADC unit 11.

The processor 9 is preferably provided with a connection 7 from the speaker 2 or DAC unit 6 in order to detect the time lapse from the transmission of the signal to the reception of signal's echo, and possibly other characteristics influencing the reflected signal.

The connection 7 between the processor 9 and the speaker 2, or between the processor 9 and DAC unit 6, facilitates for known multiplexing schemes, such as Time Divisional Multiplexing (TDM) or Frequency Divisional Multiplexing (FDM) for the output signal by the DAC unit 6 and the corresponding input processing by the processor 9.

In current platforms, there are usually a fixed set of standard sampling rates available, e.g. 16 KHz, 32 KHz, 48 KHz, 96 KHz, 192 KHz, etc. The maximum configurable sampling rate in a particular platform usually depends on the physical limitations in the sampling hardware itself, such as of the DAC unit 6, ADC unit 11 or codec 5. Although these standard sampling rates are suitable for different audio use-cases, a more flexible choice of sampling rate where the electronic device 3 can determine any frequency as the sampling rate would be preferable for ultrasound use-cases. If the ultrasound probe signal that is received by the processing unit 9 includes frequency components up to 30 KHz, it would be arguably more energy efficient for the processor 9 to have a non-standard sampling rate of 64 KHz, than a standardized sampling rate of 96 KHz. The benefit of using non-standard sampling rates is that they can lower power consumption of the electronic device 3. Furthermore, non-standard sampling rates provide additional selection of sampling frequency for the ADC unit 11 to fit the current detection phase in a use-case or to avoid interference, especially when the processor 9 utilizes FDM scheme for transmission of the probe signal and the corresponding processing.

Illustrated in FIG. 2, in a preferred embodiment of the invention, the at least one acoustic transducer 2 is transmitting acoustic probe signals at a predetermined low frequency band, wherein the acoustic signals are received by the at least one microphone 1 through the ADC unit 11 at a predetermined low sampling rate, encoding the acoustic signals, wherein the encoded acoustic signals are analyzed 20 by the processor 9.

If the processor 9 detects 21, from the analyzing 20 of the received encoded signal, a deviation, in the form of an interference in the current received frequency bands with the current sampling rate when compared to the previous said transmitted acoustic probe signals, e.g. the sampled signals is unlike said transmitted acoustic probe signals, the processor 9 instructs the ADC unit 11 to adjust 22 the sampling rate to predetermined higher frequency, thus making available additional new frequency bands (FDM) or time-slots (TDM) for the probe signal with the new increased frequency band. The processor 9 also simultaneously instructs the DAC unit 6 to adjust 23 the frequency of the probe signal that that corresponds to the said adjusted 22 sampling rate.

Should interference still be detected 21 by the processor 9 in all available frequency bands after the previous adjustment 22, the process repeats itself until an available frequency band (FDM) or time-slot (TDM) is achieved. However, if interference is not detected 24 by the processor 9, the current frequency band continues to be sampled 25 at the current sampling rate of the ADC unit 11.

Further illustrated in FIG. 2, if the device 3 is utilizing FDM, and prior transmitting a probe signal, the processor 9 detects 21 interference with the current sampling rate at all of the selectable frequency bands, processor 9, through the ADC unit 11, can adjust 22 the sampling rate to a new predetermined value, preferably to higher sampling rate frequency. And due to the connection 7 between the processor 9 and the DAC unit 6 or the speaker 2, the processor 9 can adjust 23 the probe signal to a new frequency band made available by the increased sampling rate by the ADC unit 11, which corresponds to the adjusted 22 the sampling rate.

And as shown in FIG. 3, the processor 9 receives 20 acoustic signals from the current frequency band and sampling rate, and given that no interference is detected 24 with said frequency band and sampling rate, the processor 9 then analyzes 26 all available frequency bands with the current sampling rate of the ADC unit 11. And if the processor 9 detect 40 that there is an available frequency band at a lower frequency at the current sampling rate, the processor 9 can then decrease 27 the probe signal to said lower frequency band. And the processor 9 instructs the ADC unit 11 to lower 28 the sampling rate to a predetermined sampling rate that is suitable of sampling the said new frequency band. Said probe signal with the lower frequency band is then sampled 25. However, if the analysis 26 of all available frequency bands does not show 41 an available frequency band at a lower frequency with the current sampling rate, the device 3 then continues to sample 25 at the current frequency and sampling rate. A preferred outcome of lowering both the frequency band and the sampling rate is to reduce power usage of the electronic device 3.

The at least one first transducer 1 can receive acoustic signals from an additional second transducer 2 on the electronic device 3 or from an additional second transducer 2 from at least one other third party electronic device (not shown). If the frequency band of the acoustic signals from said additional second transducer 2 does not correspond to the current sampling rate, the processor then 9 adjusts 22 the sampling rate of the second conversion unit 11 to a higher predetermined sampling rate that is suitable to sample said acoustic signals from the additional second transducer 2.

Illustrated in FIG. 4, if the device 3 is utilizing TDM, and prior to transmitting a probe signal, the processor 9 does not detect 21a any additional time slots in the current selected frequency band, nor in any of the selectable frequency bands, with the current sampling rate, the processor 9 can then adjust 22 the sampling rate of the ADC unit 11, preferably to a higher sampling rate frequency. The processor 9 can then adjust 23 a probe signal to the new selectable frequency band, correspondingly to the adjusted 22 sampling rate, and the processor 9 can then utilize 33 available time slots made available by said new selected frequency band, and those of other new frequency bands by the sample rate adjustment 22.

Also shown in FIG. 3, the processor 9 can analyze 26a available time slots in all selectable frequency bands, and if the processor 9 detect 40a available time slots at a lower frequency with the current sampling rate, the processor 9 can decrease 27a the probe signal to the available time slot in said lower frequency band, and the time slotted probe signal is then sampled 25. And due to the new lower frequency band, the processor 9 can then lower 28 the sampling rate of the ADC unit 11 to a predetermined sampling rate that is suitable of sampling the said time slot of the new frequency band. However, if the monitoring 26a of all available time slots in all available frequency bands does not show 41a an available time slot at a frequency band supported by a lower sampling rate, the device 3 then continues to sample 25 at with the available time slots at the current frequency and sampling rate. A preferred outcome of lowering both the frequency band and the sampling rate is to reduce power usage of the electronic device 3.

In one embodiment, illustrated in FIG. 5, e.g. in the use-case of presence detection, a narrowband probe signal is generated by the DAC unit 6 and is intentionally sampled 50 at a lower sampling frequency, i.e. Fₛ<2×Fₓ, by the ADC unit 11 than recommended by the Nyquist sampling theorem, i.e. Fₛ≥2×Fₓ. This under-sampling 50 would cause an intended aliasing effect, wherein the output encoded signal would acquire a new lower frequency than the original frequency of the input narrowband probe signal. However, due to the connection 7 between the processing unit 9 and the acoustic transducer 2 or the DAC unit 6, the processor 9, knowing the variables by the connection 7; such as the original frequency of the probe signal, the probe signal's time of flight, and its lower sampling rate; can determine by calculation 51 the original frequency of the narrowband probe signal, prior sampling and encoding by the ADC unit 11 for further use in detection analysis.

In another embodiment, illustrated in FIG. 6, at a current sampling rate by the ADC unit 11, whereupon the processor 9, by the DAC unit 6 utilizes the filtering device 8, wherein the filter alters 60 the original probe signal's frequency band to one with a higher or lower frequency. The processor 9 will then adjust 61 the sampling rate of the ADC unit 11 to a predetermined sampling frequency, suitable to sample the altered 60 acoustic signal. And due to the connection 7 between the processing unit 9 and the acoustic transducer 2 or the DAC unit 6, with consideration to the effect from the filter device 8, wherein the processor 9 can determine by calculation 62 the unaltered frequency of said altered probe signal.

The present invention thus refers to a method and a related electronic device 3 which may assure that at least a signal is received undistorted by an including, at least one first transducer 1 for receiving acoustic signals in a predetermined frequency band and digitizing said acoustic signals at a predetermined sampling rate, at least one second transducer 2 for transmitting acoustic signals in said predetermined frequency band corresponding to said predetermined sampling rate, an analyzing unit 9 for comparing said transmitted acoustic signals with said received acoustic signals, wherein the electronic device's analyzing unit 9 may analyze 20 the quality of said received acoustic signals, may detect 21 at least one deviation between said transmitted acoustic signals and said received acoustic signals, and may adjust 22, 23 said sampling rate and corresponding frequency band according to a set of predefined frequency bands and sampling rates.

The analyzing unit 9 may configure said acoustic signals at the lowest available sampling rate and corresponding frequency band to the electronic device 3. E.g. in order to save power the available lowest sampling for an electronic device 3 may be 8 KHz, therefore a corresponding frequency band for a signal should be no more than 4 KHz with regards to the Nyquist theorem.

The electronic device 3 further includes a first conversion unit 6 connected between said analyzing unit 9 and said at least one second transducer 2, and may transform encoded signals from said analyzing unit 9 to acoustic signals for said at least one second transducer 2.

The electronic device 3 further includes a second conversion unit 11 connected between said analyzing unit 9 and said at least one first transducer 1, and may digitize received acoustic signals from said at least one first transducer 1 to encoded signals for said analyzing unit 9. In other words digitize may include to encode received acoustic signals.

If the at least one first transducer 1 receives 20 acoustic signals and the analyzing unit 9 detects 21 a deviation, the analyzing unit 9 may adjust 22 the sampling rate of the second conversion unit 11 to a predetermined sampling rate and adjust 23 said probe signal to a predetermined frequency band corresponding with the adjusted 22 sampling rate. E.g. if the electronic device 3 is utilizing a sampling rate of 8 KHz and the analyzing unit 9 discovers a deviation due to the received acoustic signal, which should have a frequency of maximum 4 KHz with regards to the Nyquist theorem, the analyzing unit 9 may then increase the sampling rate and frequency band of the probe signal to a predetermined set available to the electronic device 3, for instance to 16 KHz for the sampling rate and correspondingly maximum 8 KHz for the probe signal, with the intention to neutralize said deviation.

If the analyzing unit 9 continues to detect 21 a deviation, the analyzing unit 9 may further adjust 22 the sampling rate of the second conversion unit 11 to a higher predetermined sampling rate and adjust 23 said probe signal to a predetermined frequency band corresponding with the adjusted 22 sampling rate. E.g. as mentioned in the previous example, should a the said initial predetermined increase not work, then another predetermined increase is utilized to 32 KHz for the sampling rate and correspondingly maximum 16 KHz for the probe signal, with the further intention to neutralize said deviation.

If the at least one first transducer 1 receives 20 acoustic signals and the analyzing unit 9 does not detect 24 at least one deviation, the second conversion unit 11 may continue to sample 25 said acoustic signals at the current sampling rate.

If the at least one first transducer 1 receives 20 acoustic signals and the analyzing unit 9 does not detect 24 at least one deviation, the analyzing unit 9 may analyze 26 available frequency bands for a probe signal with the current sampling rate. E.g. should the electronic device 3 not detect 24 any deviations during sampling, the intention for the analyzing unit 9 analyzes 26 available frequency bands is find lower sampling rates to utilize in order to save power.

If the analyzing unit 9 detects 40 an available frequency band for a probe signal at a lower frequency, the analyzing unit 9 may decrease 27 the frequency band of the probe signal transmitted to the first conversion unit 6 to the detected 40 frequency band, and may decrease 28 the sampling rate to sample 25 the new decreased 27 frequency band of the probe signal. E.g. If the current sampling rate is 32 KHz, and the analyzing unit 9 discovers that a sampling frequency of 16 KHz is available, then the analyzing unit 9 correspondingly reduces the sampling rate to 16 KHz and the probe signal frequency band to maximum 8 KHz.

If the analyzing unit 9 does not detect 41 an available frequency band for a probe signal at a lower frequency, the analyzing unit 9 may continue to sample 25 the current probe signal.

If the at least one first transducer 1 receives acoustic signals from an additional second transducer 2, wherein the frequency band of said acoustic signals does not correspond to the current sampling rate, the analyzing unit 9 may adjust 22 the sampling rate of the second conversion unit 11 to a higher predetermined sampling rate. E.g. if the sampling rate of the electronic device 3 is 32 KHz and unexpectedly discovers a deviation due to receiving a signal with a higher frequency band from an additional second transducer 2 the sampling rate is changed to predetermined higher level to 64 KHz, and may continue to increase the sampling rate frequency in a predetermined manner until the deviation disappears.

Said additional second transducer 2 may derive from another electronic device (not shown).

The electronic device 3 may be configured to also utilize Time Divisional Multiplexing TDM for transmitting and receiving signals.

If the analyzing unit 9 does not detect 21a any additional time slots for a probe signal at the current probe signal frequency band and other frequency bands with the current sampling rate, the analyzing unit 9 may adjust 22 the sampling rate of the second conversion unit 11 to a higher predetermined frequency band and may adjust 23 the probe signal frequency band to correspond with the adjusted 22 sampling rate, wherein the analyzing unit 9 utilizes 33 available time slots from the adjusted 22, 23 frequency bands of the sampling rate and probe signal. E.g. if the current sampling rate is 64 KHz and there are no available time slots for probe signals with frequencies bands at 32 KHz and lower, the sampling rate is then increased in a predetermined manner to 128 KHz in order to make available new time slots for probe signals between 32 KHz and 64 KHz.

If the at least one first transducer 1 receives 20 acoustic signals and the analyzing unit 9 does not detect 24 at least one deviation, the analyzing unit 9 may analyze 26a available time slots in all available frequency bands at the current sampling rate.

If the analyzing unit 9 detects 40a available time slots for a probe signal at a lower frequency band with the current sampling rate, the analyzing unit 9 may decreases 27a the frequency band of the probe signal transmitted to the first conversion unit 6 to the detected 40a frequency band, and may decrease 28 the sampling rate to sample 25 the time slots the new decreased 27a frequency band of the probe signal. E.g. if the current sampling rate is 64 KHz and there are available time slots for probe signals with frequencies bands at 16 KHz and lower, the sampling rate is then decreased in a predetermined manner to 32 KHz in order to make available new time slots for probe signals at 16 KHz and lower.

If the analyzing unit 9 does not detect 41a any available time slots for a probe signal at a lower frequency band with the current sampling rate, the analyzing unit 9 may continue to sample 25 the current probe signal.

The analyzing unit 9 may be configured to sample 50 received acoustic signals at lower sampling frequency lower than twice value of the highest frequency of said acoustic signal, wherein the analyzing unit 9 may determine 51 by calculation the original frequency of said acoustic signal. E.g. the analyzing unit 9 can have a predetermined sampling rate at 48 KHz, and should receive signals with frequency bands no larger than 24 KHz, however, the analyzing unit 9 can transmit a signal with a frequency of 30 KHz and receive an expected deviation through calculation by the at least one first transducer 1, thus receiving an expected deviation and a signal of 30 KHz.

The electronic device 3 may further include a filtering unit 8, wherein the filtering unit 8 alters 60 a probe signals frequency band to a higher or lower frequency, wherein the analyzing unit 9 adjusts 61 the sampling rate of the of second conversion unit 11 suitable to sample the altered probe signal, wherein the analyzing unit 9 may determine 62 by calculation the original frequency of said acoustic signal. E.g. the analyzing unit 9 can have a predetermined sampling rate at 48 KHz, and the analyzing unit 9 can transmit a signal with a frequency of 30 KHz, however due to filtering unit 8 the transmitted signal's frequency is altered higher to 50 KHz due to the filtering unit 8. The analyzing unit 9 then receives an expected deviation through calculation by the at least one first transducer 1, taking into consideration of the sampling rate of 48 KHz, the known original frequency band of 30 KHz and the tangible effects of the filtering unit 8, thus receiving an expected deviation and signal of 50 KHz.

The first conversion unit 6 and the second conversion unit 11 may be a DAC unit and an ADC unit.

The electronic device 3 may include a codec 5 that may have the same connections and functionalities of both the DAC unit 6 and the ADC unit 11.

The electronic device 3 may be configured to assure that at least a signal is received undistorted, the electronic device 3 may include at least one first transducer 1 configured to receive acoustic signals in a predetermined frequency band and may digitize said acoustic signals at a predetermined sampling rate, at least one second transducer 2 configured to transmit acoustic signals in said predetermined frequency band corresponding to said predetermined sampling rate, an analyzing unit 9 configured to compare said transmitted acoustic signals with said received acoustic signals, wherein the analyzing unit 9 may be further configured to analyze 20 the quality of said received acoustic signals, may detect 21 at least one deviation between said transmitted acoustic signals and said received acoustic signals, and may adjust 22, 23 said sampling rate and corresponding frequency band according to a set of predefined frequency bands and sampling rates.

The electronic device 3 may further include a filtering unit 8, wherein the filtering unit 8 may be configured to alter 60 a probe signals frequency band to a higher or lower frequency.

1. A method for assuring at least a signal is received undistorted by an electronic device, the method comprising:
at least one first transducer for receiving acoustic signals in a predetermined frequency band and digitizing said acoustic signals at a predetermined sampling rate;
at least one second transducer for transmitting acoustic signals in said predetermined frequency band corresponding to said predetermined sampling rate;
an analyzing unit for comparing said transmitted acoustic signals with said received acoustic signals; and
wherein the analyzing unit analyzes the quality of said received acoustic signals, detects at least one deviation between said transmitted acoustic signals and said received acoustic signals, and adjusts said sampling rate and corresponding frequency band according to a set of predefined frequency bands and sampling rates.

2. The method according to claim 1, wherein the analyzing unit compares said acoustic signals at the lowest available sampling rate and corresponding frequency band to the electronic device.

3. The method according to claim 1, wherein the electronic device further includes a first conversion unit connected between said analyzing unit and said at least one second transducer, transforming encoded signals from said analyzing unit to acoustic signals for said at least one second transducer.

4. The method according to claim 1, wherein the electronic device further includes a second conversion unit connected between said analyzing unit and said at least one first transducer, digitizing received acoustic signals from said at least one first transducer to encoded signals for said analyzing unit.

5. The method according to claim 1, wherein said acoustic signals by the at least second transducer comprise of at least a probe signal, wherein said probe signal is a transmitted acoustic signal at a predetermined frequency band and predetermined time duration.

6. The method according to claim 5, wherein the at least one first transducer receives acoustic signals and the analyzing unit detects a deviation, wherein the analyzing unit adjusts the sampling rate of the second conversion unit to a predetermined sampling rate and adjust said probe signal to a predetermined frequency band corresponding with the adjusted sampling rate.

7. The method according to claim 1 any of the previous claims, wherein the analyzing unit continues to detect a deviation, wherein the analyzing unit further adjusts the sampling rate of the second conversion unit to a higher predetermined sampling rate and adjust said probe signal to a predetermined frequency band corresponding with the adjusted sampling rate.

8. The method according to claim 1, wherein the at least one first transducer receives acoustic signals and the analyzing unit does not detect at least one deviation, wherein the second conversion unit continues to sample said acoustic signals at the current sampling rate.

9. The method according to claim 1, wherein the at least one first transducer receives acoustic signals and the analyzing unit does not detect at least one deviation, wherein the analyzing unit analyzes available frequency bands for a probe signal with the current sampling rate.

10. The method according to claim 1, wherein the analyzing unit detects an available frequency band for a probe signal at a lower frequency, wherein the analyzing unit decreases the frequency band of the probe signal transmitted to the first conversion unit to the detected frequency band, and decreases the sampling rate to sample the new decreased frequency band of the probe signal.

11. The method according to claim 1, wherein the analyzing unit does not detect an available frequency band for a probe signal at a lower frequency, wherein the analyzing unit continues to sample the current probe signal.

12. The method according to claim 1, wherein the at least one first transducer receives acoustic signals from an additional second transducer, wherein the frequency band of said acoustic signals does not correspond to the current sampling rate, the analyzing unit adjusts the sampling rate of the second conversion unit to a higher predetermined sampling rate.

13. The method according to claim 12, wherein said additional second transducer is from another electronic device (not shown).

14. The method according to claim 1, wherein the electronic device is utilizing Time Divisional Multiplexing (TDM) for transmitting and receiving signals.

15. The method according to claim 14, wherein the analyzing unit does not detect any additional time slots for a probe signal at the current probe signal frequency band and other frequency bands with the current sampling rate, wherein the analyzing unit adjust the sampling rate of the second conversion unit to a higher predetermined frequency band and adjust the probe signal frequency band to correspond with the adjusted sampling rate, wherein the analyzing unit utilizes available time slots from the adjusted frequency bands of the sampling rate and probe signal.

16. The method according to claim 14, wherein the at least one first transducer receives acoustic signals and the analyzing unit does not detect at least one deviation, wherein the analyzing unit analyzes available time slots in all available frequency bands at the current sampling rate.

17. The method according to claim 14, wherein the analyzing unit detects available time slots for a probe signal at a lower frequency band with the current sampling rate, wherein analyzing unit decreases the frequency band of the probe signal transmitted to the first conversion unit to the detected frequency band, and decreases the sampling rate to sample the new decreased frequency band of the probe signal.

18. The method according to claim 14, wherein the analyzing unit does not detect any available time slots for a probe signal at a lower frequency band with the current sampling rate, wherein the analyzing unit continues to sample the current probe signal.

19. The method according to claim 1, wherein the analyzing unit samples received acoustic signals at a lower sampling frequency than twice value of the highest frequency of said acoustic signal, wherein the analyzing unit determines by calculation the original frequency of said acoustic signal.

20. The method according to claim 1, wherein the electronic device further includes a filtering unit, wherein the filtering unit alters a probe signals frequency band to a higher or lower frequency, wherein the analyzing unit adjusts the sampling rate of the second conversion unit to a predetermined sampling frequency that is suitable to sample the altered probe signal, wherein the analyzing unit determines by calculation the original frequency of said acoustic signal.

21. The method according to claim 1, wherein the first conversion unit and the second conversion unit is a DAC unit and an ADC unit.

22. The method according to claim 21, wherein the electronic device includes a codec having the same connections and functionalities of both the DAC unit and the ADC unit.

23. An electronic device configured to assure that at least a signal is received undistorted, the electronic device comprising:
at least one first transducer configured to receive acoustic signals in a predetermined frequency band and digitizing said acoustic signals at a predetermined sampling rate;
at least one second transducer configured to transmit acoustic signals in said predetermined frequency band corresponding to said predetermined sampling rate;
an analyzing unit configured to compare said transmitted acoustic signals with said received acoustic signals; and
wherein the analyzing unit is further configured to analyze the quality of said received acoustic signals, detect at least one deviation between said transmitted acoustic signals and said received acoustic signals, and adjust said sampling rate and corresponding frequency band according to a set of predefined frequency bands and sampling rates.

24. The electronic device according to claim 23, wherein the electronic device further includes a filtering unit, wherein the filtering unit is configured to alter a probe signal's frequency band to a higher frequency.
